(19) United States
(12) Patent Application Publication
(10) Pub. No.: US 2015/0207022 A1
(43) Pub. Date: Jul. 23, 2015

(54) System for the production of single crystal semiconductors and solar panels using the single crystal semiconductors

(71) Applicant: Grain Free Products, Inc., Alexandria, VA (US)

(72) Inventor: Fritz Juergen Wisotzki, Darmstadt (DE)

(21) Appl. No.: 14/633,654

(22) Filed: Feb. 27, 2015

Related U.S. Application Data
(63) Continuation-in-part of application No. 13/026,228, filed on Feb. 12, 2011, now abandoned.

(30) Foreign Application Priority Data
Mar. 16, 2010 (EP) 10002736

(51) Int. Cl. H01L 31/18; C30B 33/08; C30B 23/02; H01L 31/0392; C30B 29/08; C30B 29/48; H01L 31/0445; C30B 19/12; C30B 29/02

(52) U.S. Cl. CPC H01L 31/1836; C30B 19/12; C30B 33/08; C30B 23/025; C30B 29/02; C30B 29/08; C30B 29/48; H01L 31/0445; H01L 31/03925; H01L 31/1892; H01L 31/186

(57) ABSTRACT

A process and the required technical arrangement has been developed to produce single crystal solar panels or otherwise used semiconductors, which starts with the raw material to produce single crystal copper ribbons, extruded directly from the melt, with unharmed and optical surfaces onto which in the next unit a silicon or germanium film will be deposited. In the next unit the copper ribbon will be removed from the silicon film, whilst a hard plastic support or ceramic support is mounted, leaving copper contours on the silicon film to be used as electrical conductors or contacts. In the next unit a thin film is deposited of II-VI compounds that enhance the infrared sensitivity of the base film of silicon or germanium up to 56% of the incoming light. This technology guarantees the lowest possible cost in production of the highest possible efficiency of materials for infrared applications and electronic applications.

### CROSS REFERENCE TO RELATED APPLICATION

This application is a Continuation-In-Part of U.S. patent application Ser. No. 13/026,228, filed on Feb. 12, 2011, which is based on and claims the benefit of European Patent Application No. 10002736.6/EP10002796, filed Mar. 16, 2010, which are incorporated herein by reference.

### FIELD OF THE INVENTION

The present invention relates to a process and technical arrangement for the low cost production of ready to be used solar panels and otherwise used semiconductors, consisting of single crystal ribbons of silicon or germanium, truly interfaced with deposited II-VI compound single crystal films, having copper electrical contacts or contours a true single crystal structure, leading to an efficiency for solar applications of up to 56% of the incoming light. (II-VI compounds combine elements from groups IIB and VIA of the periodic table.)

### DESCRIPTION OF THE PRIOR ART

To use single crystal structures of silicon or germanium, one has to presently use silicon or germanium wafers, which are cut from grown, in bulk single crystal materials, and those wafers have to be refurbished by a very cost intensive process. Impurities implanted within, however, can never be fully removed. The same is valid for any production of solar panels or semiconductors, if machining of surfaces is involved and if the surfaces of importance for the efficiency have been exposed to air. The interface between coatings and substrates will have a higher resistivity and the lifetime of the coatings is highly limited.

U.S. Pat. No. 4,596,626, issued on Jun. 24, 1986, to Shlicta et al., discloses a method of making a solar cell utilizing a single crystal copper substrate and growing single crystal semiconductor layers on the substrate, but does not disclose that oxygen from the air is excluded throughout the process, as in the instant invention.

U.S. Pat. No. 7,517,465, issued on Apr. 14, 2009, to Guha et al., discloses chemically etching back reflective layers, but does not disclose the use of single crystal substances, as in the instant invention.

U.S. Pat. No. 8,322,299, issued on Dec. 4, 2012, to Yu et al., discloses a semiconductor manufacture apparatus in an inert gas atmosphere, but does not disclose the use of single crystal substances, as in the instant invention.

U.S. Patent Application Publication No. 2009/0242032, published on Oct. 1, 2009, to Yamazaki et al., discloses using copper as a material in a back reflective material for a solar cell, and including layers with impurities, unlike in the instant invention where impurities are excluded from all layers.

U.S. Patent Application Publication No. 2010/0282304, published on Nov. 11, 2010, to Wu et al, discloses an online process in which films are deposited by a falling film technique in sequence onto substrates, but does not disclose that oxygen from the air is excluded throughout the process, as in the instant invention.

U.S. Patent Application Publication No. 2011/0061715, published on Mar. 17, 2011, discloses removing portions of a copper back electrode via etching in a solar cell, but does not disclose the use of single crystal materials, as in the instant invention.

U.S. Patent Application Publication No. 2011/0240120, published on Oct. 6, 2011, to Ronda et al., discloses use of II-VI compounds in active layers in solar cells, including HgCdTe, but does not disclose that they have a single crystal structure, as in the instant invention.

U.S. Patent Application Publication No. 2011/0277813, published on Nov. 17, 2011, to Rogers et al., discloses use of II-VI compounds in active layers in solar cells, including ZnSe, ZnS and CdTe, but does not disclose that all layers have a single crystal structure, as in the instant invention.

U.S. Patent Application No. 2013/0014799, published on Jan. 17, 2013, to Vidu et al., discloses the use of single crystal material having active II-VI material layers in solar cells, but does not disclose that the layers are single crystal, as in the instant invention.

Japanese Patent No. 63-199049, published on Aug. 17, 1988, to Sawada et al, discloses an extrusion system that has a minor fault in it, in that it is extruding upwards and flat, working against gravity, which leads to high dislocation density in the crystal structure of the extruded material. It does not disclose what material the extrusion jet is made of and how it controls the outflow. It is likely to be difficult to work, due to the capillary force that its description mentions briefly. Extruding against capillary force results in high dislocation density, which is harmful to the crystal structure and the existence of free electrons. The instant invention uses a slightly downwards mounted jet to use the support of gravity to avoid high dislocation density, and controls the outflow via a radio frequency coil, mounted around the extrusion jet to overcome the capillary force. This alone is needed to get the high density of free electrons as a binding force between the base copper and the first deposited material, which then in turn has on its surface free electrons of a similar magnitude as in the base copper foil. Any process describe above, as known from the live experiments, will end up in not very uniform films, which will not have a decent lifetime, and cannot compete cost-wise with the instant invention.

The present invention is different from the prior art because it has a total online production system and method which avoids any of the materials used being contaminated with air, from the base plate to the finished product. None of the prior art references disclose this in one system that produces an entirely single crystal multi-layered product. With a product based on what they describe, it is an expensive task to get the product cleaned, and even the best cleaning cannot produce a product with the quality of the process of the instant invention. The instant invention uses high vacuum and inert gas of the highest purity during its process from beginning to end. This produces unexpected properties, such as high electrical and thermal conductivity, that make the instant invention non-obvious over the prior art.

### SUMMARY OF THE INVENTION

This invention leads to the utmost use of materials in their highest: purity and lowest resistance, with lowest corrosion factors, leading to extreme efficiency at low costs, caused by the disclosed online process, in which those materials do not need any extra handling to remove imperfections and impurities.

As a base and start up material, the present invention uses a single crystal foil, which is grown to the quantity needed without any further mechanical treatment, while the prior art starts from machined single crystal surfaces. The base material of the instant invention is free of strain, and that means that rapid temperature changes do not harm the coatings put on top of the base material. Coatings on a strained single crystal material surface have the tendency to fall off, if they undergo rapid thermal changes, which cannot be avoided in a good number of applications.

Since in the process of the present invention, there is no coating onto the base plates after they have been exposed to air, the cleanliness of the interface is perfect and no impurities are implanted in the interface. This is all done in an on line inert atmosphere system to avoid implanting such impurities.

The binding energy of the free electrons on such base surfaces interweb the coating in a way that creates a direct epitaxic connection into the atomic structure of the base plate. Those free electrons only exist on such grown, unarmed single crystal surfaces. The next coating has the same quality of surface until it comes to air. The throughput of energy from the last layer of the coating down to the electrodes has almost no resistance. The efficiency coefficient of solar panels of the instant invention comes up to about 56% of incoming radiation having a wavelength of 10.6 microns. If a radiation level of ten watts comes to the surface of the instant inventions sensing material, 5.6 watts will leave the cell as electricity, regardless of the source of the radiation, whether from the sun, the human body, or any other source.

Using such grown base material is definitely less expensive than using refurbished materials. The present invention's economic achievement of energy production is significant. Presently, solar cells have an efficiency coefficient of only 21% because of their polycrystalline structure. Use of refurbished single crystal silicon is too expensive to be useful, other than in the electronic sector.

The present invention includes an online process in which single crystal films will be deposited by a falling film technique in sequence onto substrates which have a true and unharmed single crystal surface comprising the steps of: laying down a single crystal copper substrate, having a surface that is left unmachined and untreated; growing a single crystal metalloid substrate, having a surface that is left unmachined and untreated, onto the unmachined surface copper substrate; and growing single crystal II-VI compound structure onto the unmachined surface of the metalloid substrate. The online process may include the copper substrate, the metalloid substrate, and the II-VI compound structure are all interwebbed; the entire online process takes place in an inert gas atmosphere; aside from the materials used to form the single crystals and the inert gas, and materials used in masking and etching, only materials selected from the group comprising stainless steel and graphite are used in the online process; and the online process passes through control gates and chambers, in the following sequence: a material cleaning and control gate; a copper ribbon productions chamber, wherein the pressure is reduced to not more than ten millibars, and the chamber is then flooded with a mixture of nitrogen and hydrogen, then a copper ribbon is extruded directly from molten copper through an isotropic graphite jet, having optically flat inside surfaces; a second control gate, through which the copper ribbon passes: a germanium deposition chamber, filled with argon, where evaporated germanium falls as a deposited film onto the copper ribbon; a third control gate, through which the copper ribbon with the germanium film passes; an etching and support mounting chamber, in which the bottom of the copper ribbon is masked, and most of the copper ribbon is chemically removed and replaced with material selected from the group comprising ceramics and hard plastics, leaving copper contacts that interface directly with the germanium film; a fourth control gate, through which the germanium film with the copper contacts passes; a compound deposition chamber, filled with argon, where an evaporated II-VI compound falls as a deposited film onto the germanium film; and; an unloading and testing chamber, where the II-VI compound film and the germanium film with copper contacts come to air and exit for further handling.

The present invention includes an online process comprising the steps of: laying down a copper single crystal substrate, having a surface that is left unmachined and untreated; depositing a metalloid which grows from the unmachined surface of the copper substrate into a true single crystal structure; chemically removing the majority of the copper substrate to leave copper contacts that are interwebbed with the crystal structure of the metalloid; and replacing the portion of the copper substrate that has been removed with material selected from the group comprising ceramics and hard plastics. The online process further includes: the copper substrate, the metalloid substrate, and a II-VI compound structure are all interwebbed; the entire online process takes place in an inert gas atmosphere; aside from the materials used to form the single crystals and the inert gas, and materials used in masking and etching, only materials selected from the group comprising stainless steel and graphite are used in the online process; and the online process passes through control gates and chambers, in the following sequence: a material cleaning and control gate; a copper ribbon productions chamber, wherein the pressure is reduced to not more than ten millibars, and the chamber is then flooded with a mixture of nitrogen and hydrogen, then a copper ribbon is extruded directly from molten copper through an isotropic graphite jet, having optically flat inside surfaces; a second control gate, through which the copper ribbon passes: a germanium deposition chamber, filled with argon, where evaporated germanium falls as a deposited film onto the copper ribbon; a third control gate, through which the copper ribbon with the germanium film passes; an etching and support mounting chamber, in which the bottom of the copper ribbon is masked, and most of the copper ribbon is chemically removed and replaced with material selected from the group comprising ceramics and hard plastics, leaving copper contacts that interface directly with the germanium film; a fourth control gate, through which the germanium film with the copper contacts passes; a compound deposition chamber, filled with argon, where an evaporated II-VI compound falls as a deposited film onto the germanium film; and an unloading and testing chamber, where the II-VI compound film and the germanium film with copper contacts come to air and exit for further handling.

The present invention includes an online process used to form a solar panel, comprising the steps of: laying down a single crystal copper substrate, having a surface that is left unmachined and untreated; growing a single crystal metalloid substrate onto the unmachined surface of the copper substrate, wherein the metalloid substrate is a framed and protected metalloid film of a defined thickness, having a surface that left unmachined and untreated, as the copper substrate includes copper contacts having single crystal structure at the bottom of the metalloid film; and growing a single crystal II-VI compound structure onto the unmachined surface of the metalloid substrate, wherein compound structure is a single crystal coating of a II-VI compound over the metalloid film. The online process further including the copper substrate, the metalloid substrate, and the II-VI compound structure are all interwebbed; the entire process takes place in an inert gas atmosphere; aside from the materials used to form the single crystals and the inert gas, and materials used in masking and etching, only materials selected from the group comprising stainless steel and graphite are used in the online process; and the online process passes through control gates and chambers, in the following sequence: a material cleaning and control gate; a copper ribbon productions chamber, wherein the pressure is reduced to not more than ten millibars, and the chamber is then flooded with a mixture of nitrogen and hydrogen, then a copper ribbon is extruded directly from molten copper through an isotropic graphite jet, having optically flat inside surfaces; a second control gate, through which the copper ribbon passes: a germanium deposition chamber, filled with argon, where evaporated germanium falls as a deposited film onto the copper ribbon; a third control gate, through which the copper ribbon with the germanium film passes; an etching and support mounting chamber, in which the bottom of the copper ribbon is masked, and most of the copper ribbon is chemically removed and replaced with material selected from the group comprising ceramics and hard plastics, leaving copper contacts that interface directly with the germanium film; a fourth control gate, through which the germanium film with the copper contacts passes; a compound deposition chamber, filled with argon, where an evaporated II-VI compound falls as a deposited film onto the germanium film; and an unloading and testing chamber, where the II-VI compound film and the germanium film with copper contacts come to air and exit for further handling.

Accordingly, it is a principal object of the invention to provide materials that may be used in solar panels.

It is another object of the invention to provide improved semiconductors.

It is a further object of the invention to provide materials with low electrical resistance.

Still another object of the invention is to provide materials with low thermal resistance.

It is an object of the invention to provide improved elements and arrangements thereof in an apparatus for the purposes described which is inexpensive, dependable and fully effective in accomplishing its intended purposes.

These and other objects of the present invention will become readily apparent upon further review of the following specification and drawings.

### BRIEF DESCRIPTION OF THE FIGURES

FIG. 1 is a diagrammatic representation of unmachined extruded copper ribbon, grown directly from the melt.

FIG. 2 is a diagrammatic representation of single crystal silicon or germanium film, deposited over single crystal copper foil.

FIG. 3 is a diagrammatic representation of single crystal silicon or germanium film, over a hard plastic or ceramic support and single crystal electrical contacts or contours.

FIG. 4 is a diagrammatic representation of a single crystal film of II-IV compounds, over single crystal silicon or germanium film, over a hard plastic or ceramic support and single crystal electrical contacts or contours.

FIG. 5 is a diagrammatic representation of the online process.

FIG. 6 is a microphotograph of a thin copper film, deposited by sputtering from a single crystal copper target onto a high density glass plate.

FIG. 7 is a diagrammatic representation of sputtering a grained target material unto a grained substrate.

FIG. 8 is a diagrammatic representation of sputtering a grained target material unto a single crystal substrate.

FIG. 9 is a diagrammatic representation of sputtering a single crystal target material unto a single crystal substrate.

Similar reference characters denote corresponding features consistently throughout the attached drawings.

### DETAILED DESCRIPTION OF THE INVENTION

It has been discovered in high energy laser applications, that if a single crystal surface of a material has been mechanically treated, a large difference in quality occurred, compared with a single crystal surface, which has an unharmed, as grown, single crystal structure. In the present invention, the base is grown as a single crystal surface, which has not been harmed with any machining or chemical treatment prior to deposited a thin film. It has been tried and found in research many years ago, that a machined single crystal surface will not tolerate a uniform film distribution, but usually ends up in agglomerations (i.e., clouds) of the deposited material. Examples are zinc selenide or gallium selenide deposited on silicon waters cut from bulk crystals.

On unharmed single crystal surfaces of any material, free electrons exist in a very high density, which can be used as a webbing source, binding oncoming coating material onto the surface of the substrate, as no other process will permit. This leads to the highest transfer of energy from one layer to the next, having practically no resistance to overcome. The lifetime of such stackings will be ultimate, because there are no impurities implanted during the whole process.

In the fully developed online process, provisions have been made, that the surfaces of the single crystal structures are not in contact with air or any particles of any material, because the environment for the process is of high quality stainless steel, and the materials used inside do not chemically react with silicon, germanium or copper.

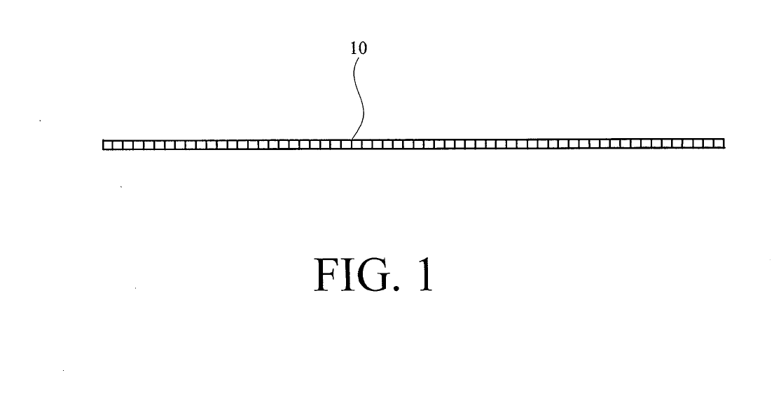

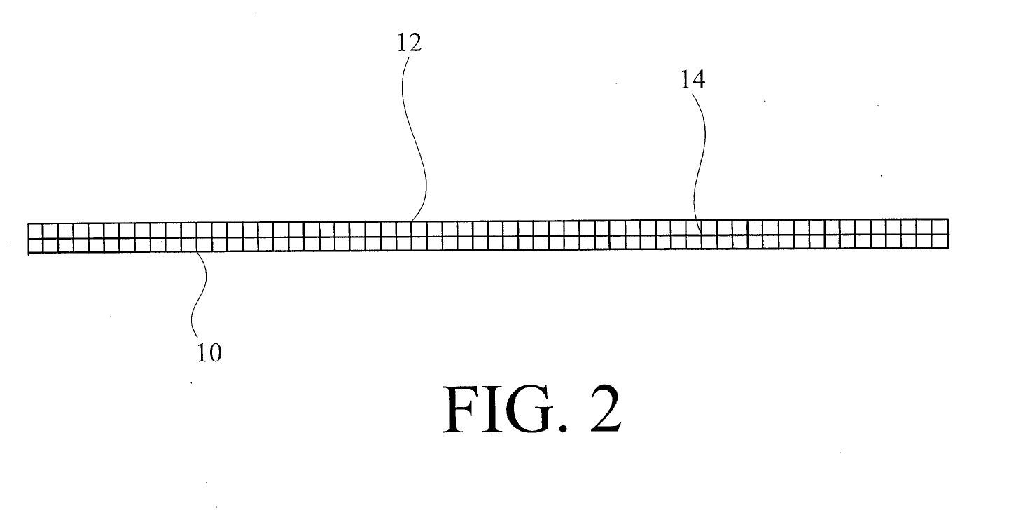

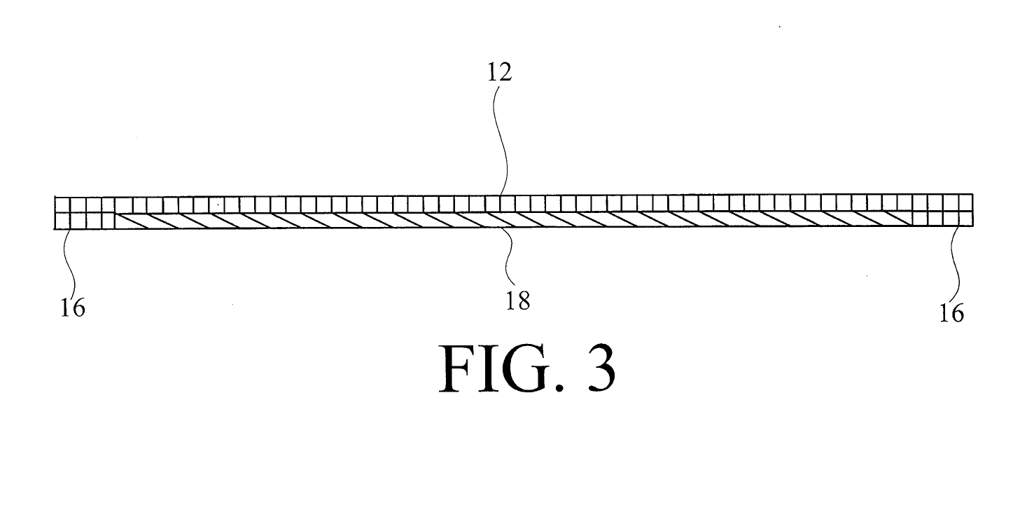

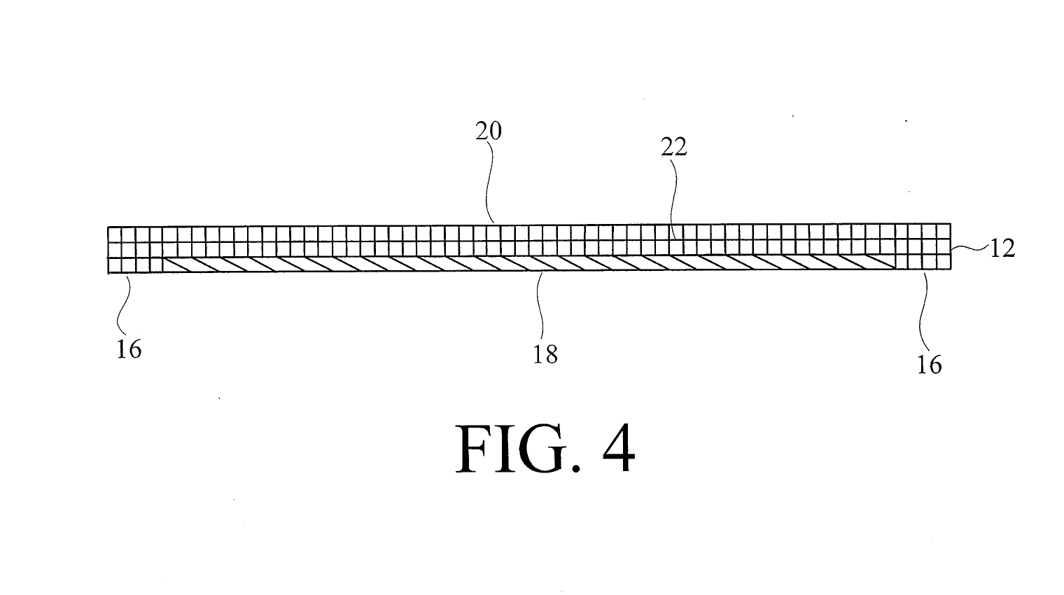

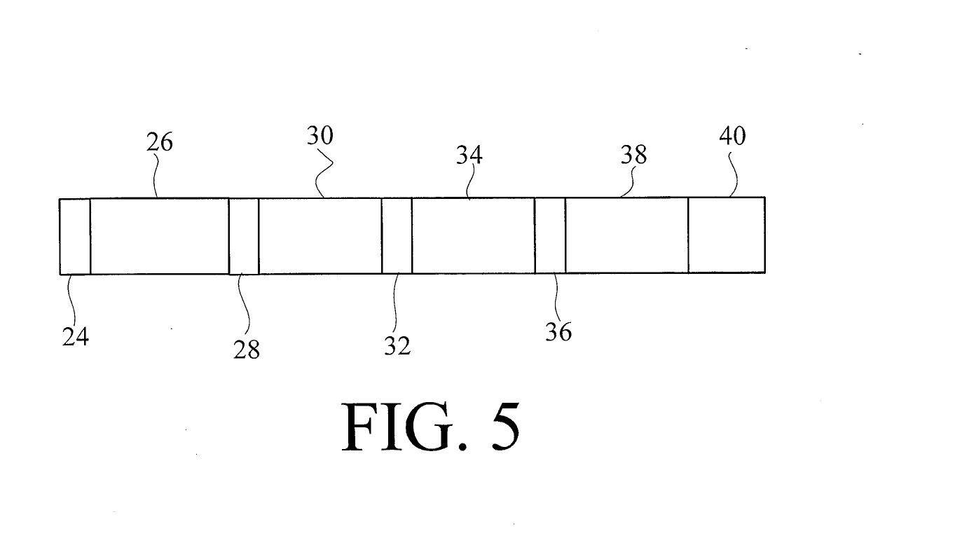

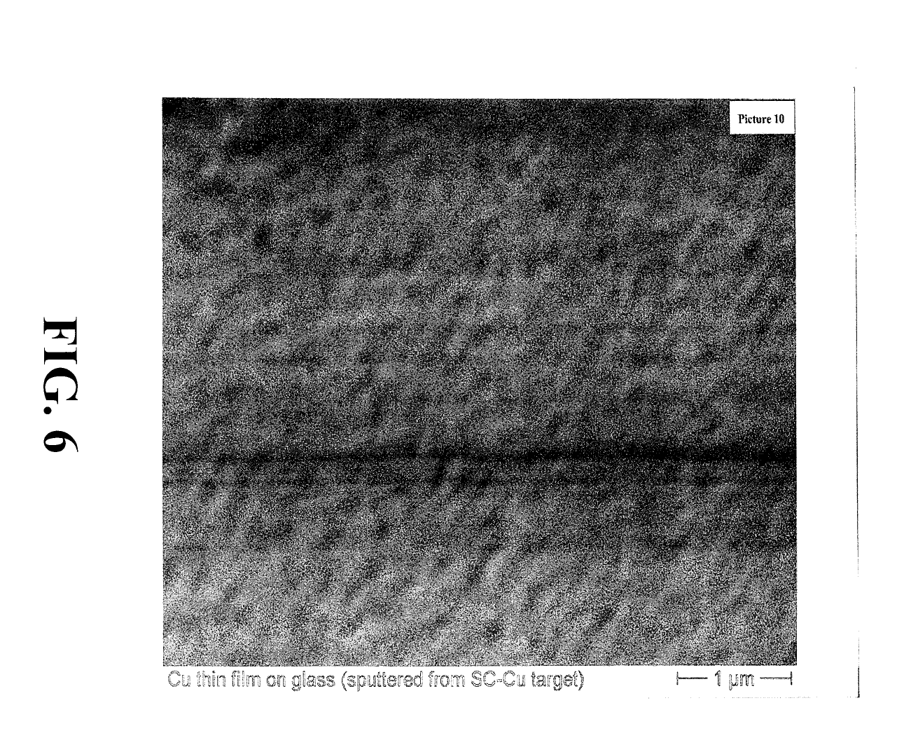

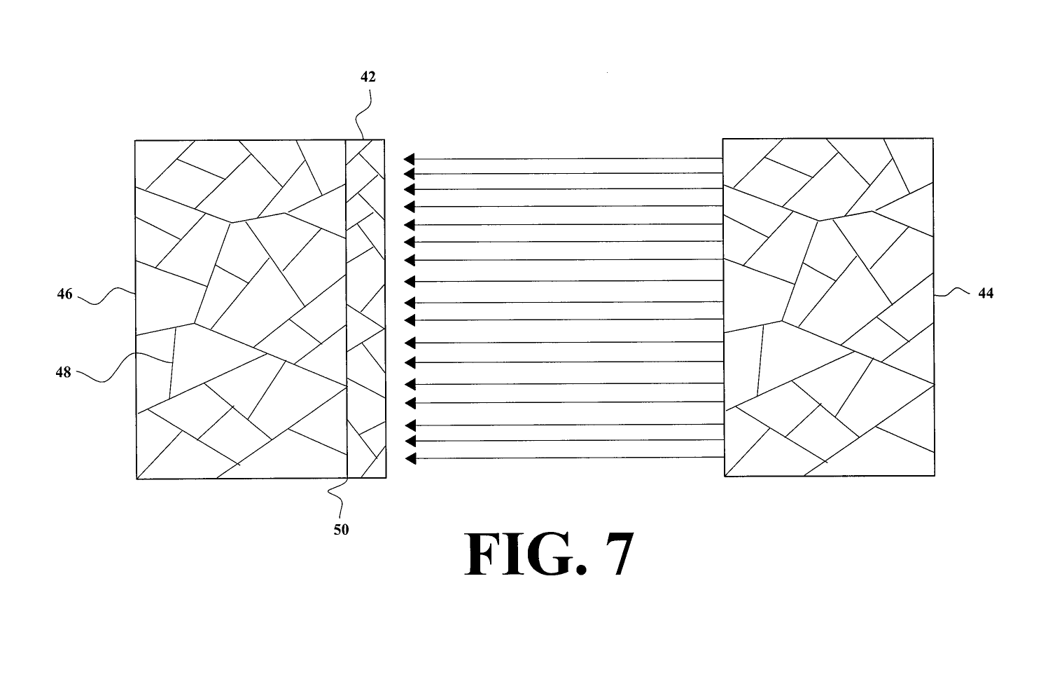

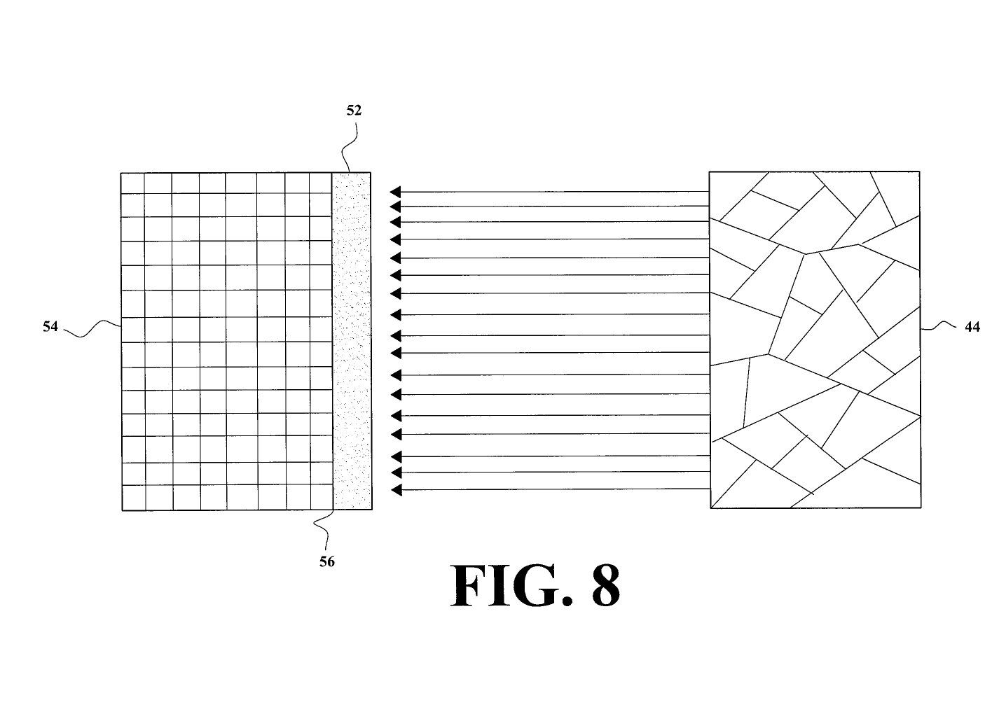

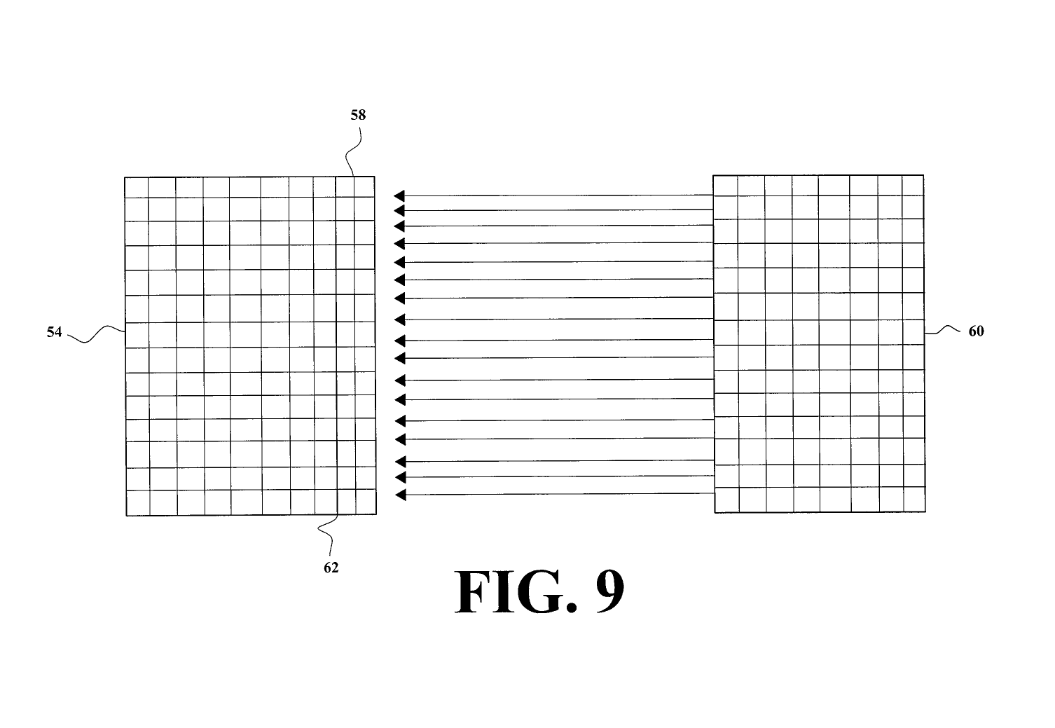

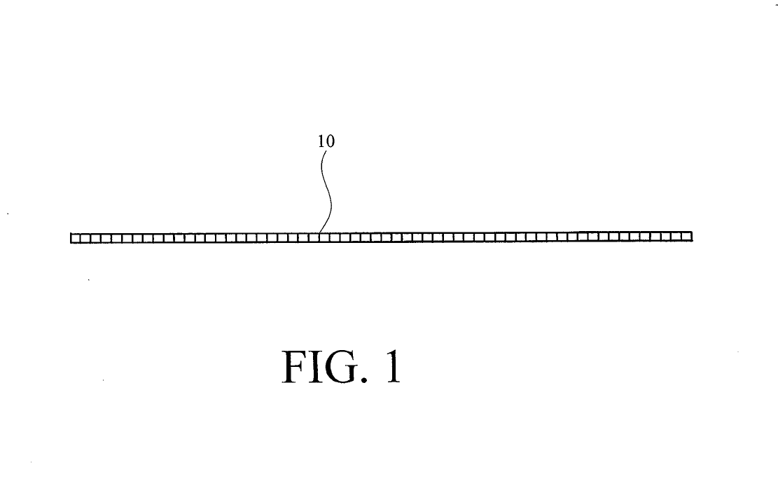

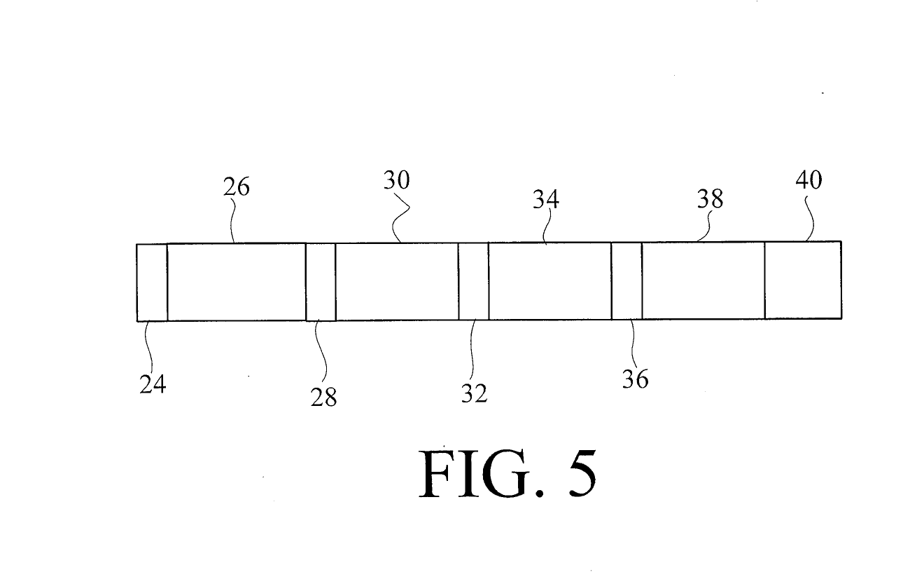

FIGS. 1 to 4 illustrate the low cost online serial production of single crystal silicon and germanium ribbons, grown as single crystal films on a copper foil, which will be chemically removed to leave contours for electrical purposes. FIG. 5 illustrates the principle of an online process to produce ready to be used solar panels and otherwise used semiconductors, that consist of true single crystal silicon or germanium ribbons, with deposited single crystal films of II-IV compounds, which have single crystal electrical contacts or contours. All single crystal structures are truly interwebbed into each other, and the interface between the structures has the lowest possible resistivity, increasing the efficiency coefficient from 49% to 56% of the incoming light, with a wave length of 10.6 microns at an angle of zero degrees. The whole online process takes place under a high purity inert gas atmosphere, and only stainless steel and high purity graphite are used in the environment, leading to the highest purity and the lowest corrosion, in particular between the interfaces of the different materials.

At the beginning of the line is the material cleaning and control gate 24 shown in FIG. 5. Chambers 26, 30, 34 and 38 are separated by material insert and control gates 28, 32 and 36. The base for deposition is a copper ribbon or foil 10, shown in FIG. 1; extruded directly from the melt in the first process unit, the copper ribbon production chamber 26. The chamber is evacuated prior to extrusion down to three to ten millibars. During heating to melt the copper, the chamber is flooded with inert gas, preferably of a mixture of nitrogen and hydrogen. The hydrogen is used to remove remaining oxygen molecules down to the lowest possible concentration. The other chambers are filled with argon.

The copper ribbon or foil is extruded through a high density, isotropic formed graphite slot or jet, which has optically flat inside surfaces. Only from such a molded graphite exit can copper be extruded to the required quality. No other material will permit copper to be extruded to such a quality. In general, graphite is the only adequate crucible material for copper.

The copper ribbon has optical quality surfaces and those surfaces are free of strain, except from the force of gravity, which cannot be eliminated. At the minor thickness of the film and the uniformity of the thickness in length, the strain is also uniform along the length of the substrate. The surfaces of the copper ribbon are not machined or subjected to any chemical treatment.

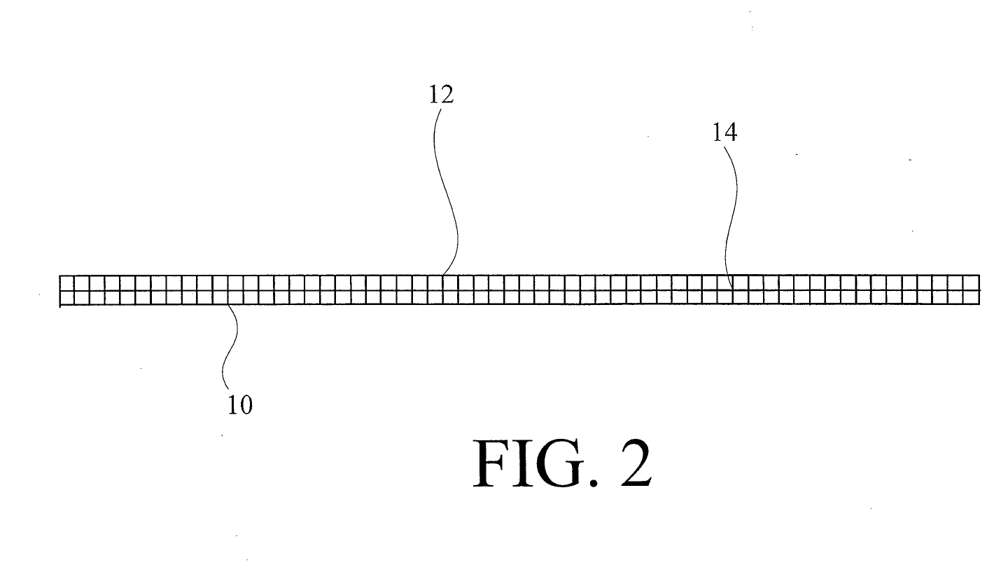

The second process unit, the silicon or germanium deposition chamber 30, holds the evaporation process of silicon or germanium in form of a falling film 12 onto the unharmed single crystal surface of the copper ribbon 10 as shown in FIG. 2. Here the force of gravity is of support, and thickness monitoring of the deposited film permits a highly uniform deposition of silicon and germanium on the single crystal copper ribbon. It has been discovered, that within a few atomic layers, a true silicon or germanium single crystal structure is growing up to the required thickness. There is low electrical and thermal resistance at the interface 14 between the two single crystal structures 10 and 12.

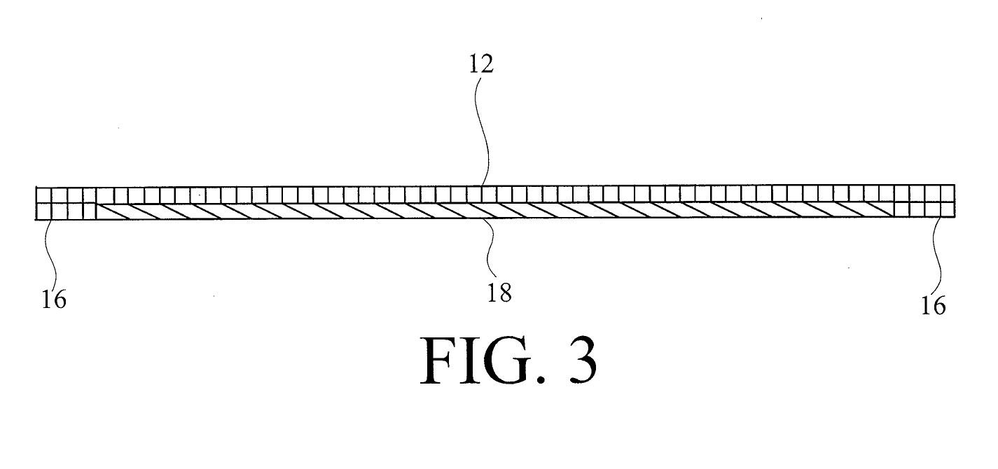

In the next online unit, the etching and support mounting chamber 34, masking of the copper contours at the bottom of the silicon or germanium films is undertaken in such a way, that the surface of the single crystal silicon or germanium film is not machined, chemically treated, or harmed by any means, and the copper film is removed in such a way, that either contacts and/or contours 16 of single crystal copper are left at the bottom of the silicon/germanium film, as shown in FIG. 3 but most of the copper ribbon is chemically removed and replaced by a hard plastic or ceramic support 18. The contacts/contours that are left from the copper ribbon directly interface with the silicon/germanium film.

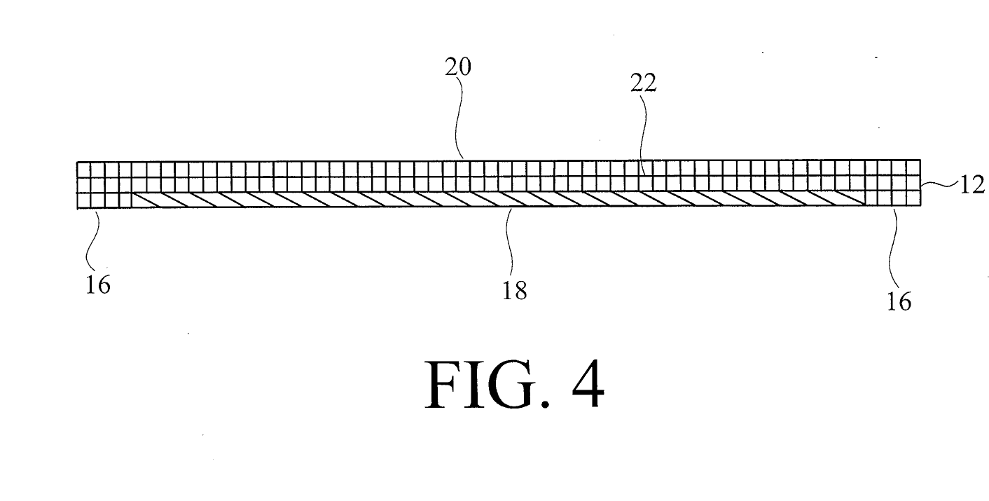

The final online stage, which takes place in the deposition of II-VI compound chamber 38, is the falling film deposition of a II-VI compound which will interweb itself in true single crystal structure into the single crystal structure of the silicon or germanium surface, as shown in FIG. 4. The highly sensitive thickness control will ensure that precision in the deposited layers of the II-VI compounds is established and there is no strain between the films, with the lowest possible electrical and thermal resistivity at the interface 22 between the single crystal layers, increasing the transfer of energy to the utmost.

The last station in the sequence is the disconnecting and framing sector, including the unloading and testing chamber 40, where the materials come to air and exit the system for further handling.

The finished product may be used to construct a solar panel consisting of a framed and protected silicon or germanium film a defined thickness, which has a single crystal coating of a II-VI compound and copper contacts and/or contours in single crystal structure at the bottom of the silicon film, with sizes up to 200×600 millimeters.

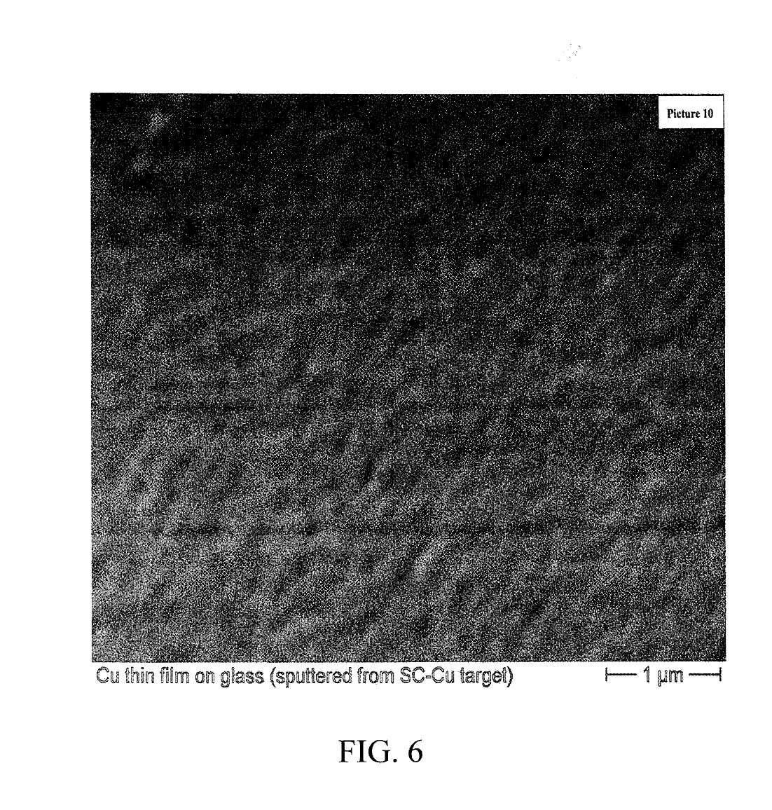

FIG. 6 is a microphotograph of a thin copper film, deposited by sputtering from a single crystal copper target onto a high density glass plate. Clouding is a problem if a film of metal or semiconductor is deposited, regardless of by what method, onto a machined surface of anything, be it a single crystal silicon wafer or something else. This clouding is very homogenous, because the material comes from a homogenous single crystal sputtering target, but since the base is not an unharmed single crystal surface, the clouding takes place, because of the missing free electrons, which if they were present, would order the structure of the deposited material into the structure of the base material.

This problem is known to all existing industries, and the problem cannot be cured, unless one uses unmachined, as grown, single crystal surfaces, which hold the free electrons and lower the dislocation density, increasing the binding force between the base and the deposited film.

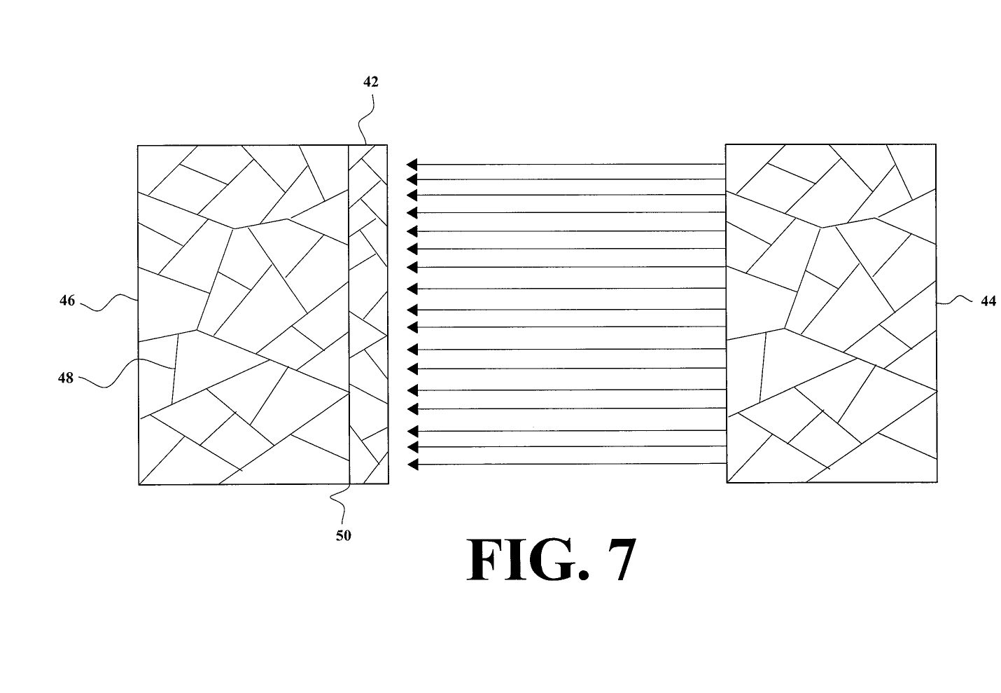

FIG. 7 shows what happens when a thin film 42 of grained sputter target material 44 is deposited on a grained substrate material 46. The target material plus impurities from grain boundaries 48 in the target material are deposited on the grained base material. The result is that the deposited film will have a grain structure with impurities from the target, and if the surface of the substrate has been machined, the interface 50 will be under strain.

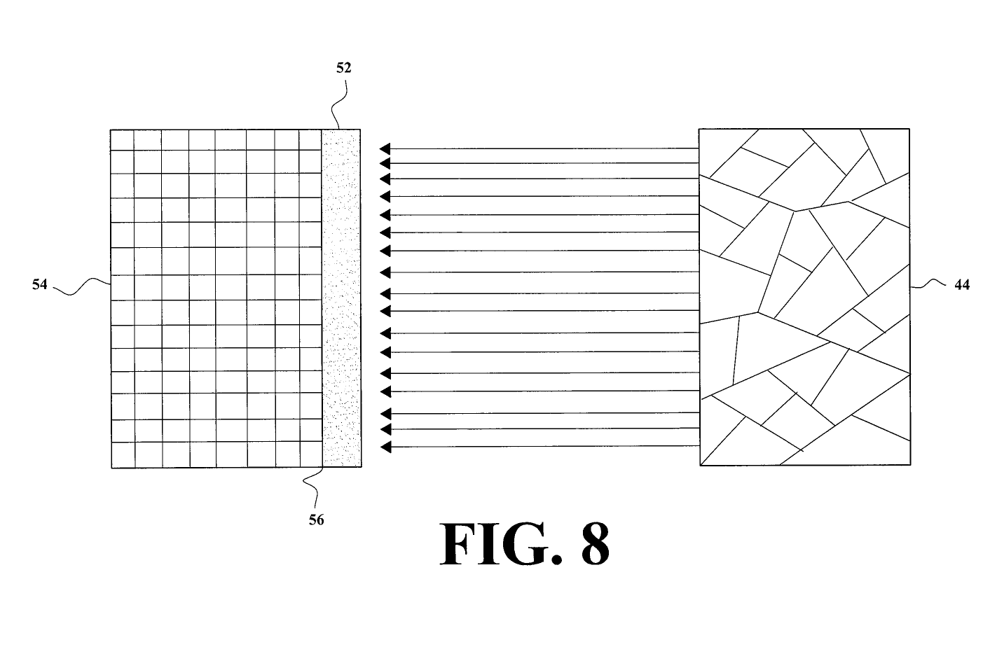

FIG. 8 shows what happens when a thin film 52 of grained sputter target material 44 is deposited on an ungrained substrate material 54 having a machined surface. The target material plus impurities from grain boundaries in the target material are deposited on the single crystal base material having a machined surface. The result is that the interface 56 is under stain. As the target has a grain structure, the impurities deposited on the single crystal substrate surface will create wild growth by acting as seeds, and the film 52 will never have a perfect crystal structure.

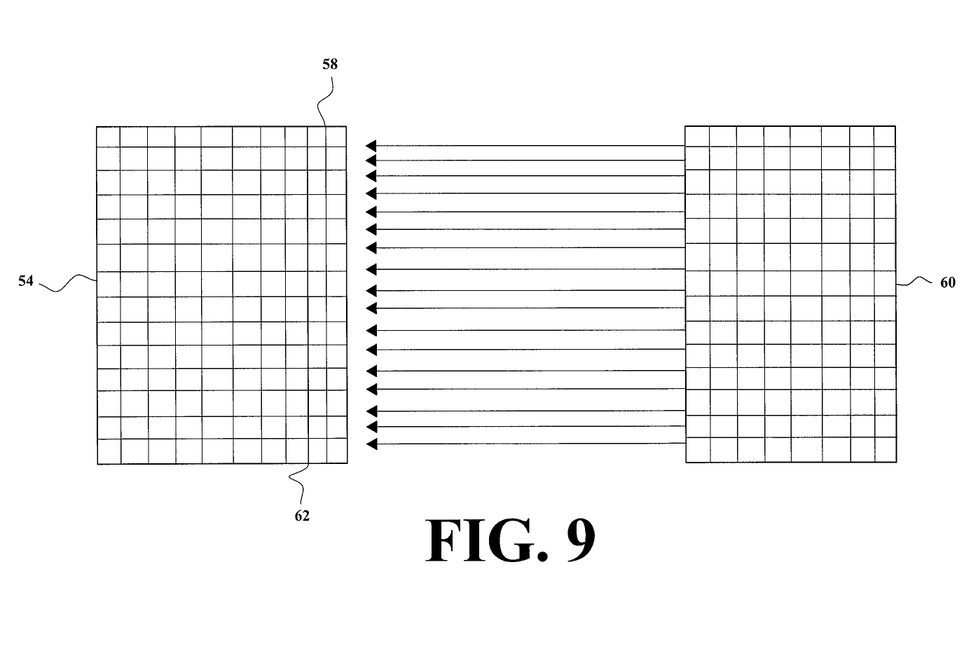

FIG. 9 shows what happens when a thin film 58 of single crystal sputter target material 60 is deposited on an ungrained substrate material 54 that is a grown single crystal, not having a machined surface. The deposited film will also grow as a single crystal structure, taking over the orientation of the substrate surface crystal orientation. There is no strain in the interface 62, and any rapid thermal changes do not peel off the deposited thin film or lead to hair thin cleavage in the film 58. This illustrates that the present invention is the ideal technology to create a perfect chip or optical component.

It is to be understood that the present invention is not limited to the embodiments described above, but encompasses any and all embodiments within the scope of the following claims.

All patents and publications mentioned in this specification are indicative of the levels of those skilled in the art to which the invention pertains. All patents and publications are herein incorporated by reference to the same extent as if each individual publication was specifically and individually indicated to be incorporated by reference.

It is to be understood that while a certain form of the invention is illustrated, it is not to be limited to the specific form or arrangement herein described and shown. It will be apparent to those skilled in the art that various changes may be made without departing from the scope of the invention and the invention is not to be considered limited to what is shown and described in the specification and any drawings/figures included herein.

One skilled in the art will readily appreciate that the present invention is well adapted to carry out the objectives and obtain the ends and advantages mentioned, as well as those inherent therein. The embodiments, methods, procedures and techniques described herein are presently representative of the preferred embodiments, are intended to be exemplary and are not intended as limitations on the scope. Changes therein and other uses will occur to those skilled in the art which are encompassed within the spirit of the invention and are defined by the scope of the appended claims. Although the invention has been described in connection with specific preferred embodiments, it should be understood that the invention as claimed should not be unduly limited to such specific embodiments. Indeed, various modifications of the described modes for carrying out the invention which are obvious to those skilled in the art are intended to be within the scope of the following claims.

What is claimed is:

1. An online process in which single crystal films will be deposited by a falling film technique in sequence onto substrates which have a true and unharmed single crystal surface, comprising the steps of:
laying down a single crystal copper substrate, having a surface that is left unmachined and untreated;
growing a single crystal metalloid substrate, having a surface that is left unmachined and untreated, onto the unmachined surface copper substrate; and
growing a single crystal II-VI compound structure onto the unmachined surface of the metalloid substrate.

2. The online process according to claim 1, wherein the metalloid substrate is composed of germanium.

3. The online process according to claim 1, wherein the II-VI compound is composed of zinc and selenium.

4. The online process according to claim 1, wherein the II-VI compound is composed of zinc and sulfur.

5. The online process according to claim 1, wherein the II-VI compound is composed of cadmium and tellurium.

6. The online process according to claim 1, wherein the II-VI compound is composed of cadmium, mercury and tellurium.

7. The online process according to claim 1, wherein:
the copper substrate, the metalloid substrate, and the II-VI compound structure are all interwebbed;
the entire online process takes place in an inert gas atmosphere;
aside from the materials used to form the single crystals and the inert gas, and materials used in masking and etching, only materials selected from the group comprising stainless steel and graphite are used in the online process; and
the online process passes through control gates and chambers, in the following sequence:
a material cleaning and control gate;
a copper ribbon productions chamber, wherein the pressure is reduced to not more than ten millibars, and the chamber is then flooded with a mixture of nitrogen and hydrogen, then a copper ribbon is extruded directly from molten copper through an isotropic graphite jet, having optically flat inside surfaces;
a second control gate, through which the copper ribbon passes:
a germanium deposition chamber, filled with argon, where evaporated germanium falls as a deposited film onto the copper ribbon;
a third control gate, through which the copper ribbon with the germanium film passes;
an etching and support mounting chamber, in which the bottom of the copper ribbon is masked, and most of the copper ribbon is chemically removed and replaced with material selected from the group comprising ceramics and hard plastics, leaving copper contacts that interface directly with the germanium film;
a fourth control gate, through which the germanium film with the copper contacts passes;
a compound deposition chamber, filled with argon, where an evaporated II-VI compound falls as a deposited film onto the germanium film; and
an unloading and testing chamber, where the II-VI compound film and the germanium film with copper contacts come to air and exit for further handling.

8. An online process, comprising the steps of:
laying down a copper single crystal substrate, having a surface that is left unmachined and untreated;
depositing a metalloid which grows from the unmachined surface of the copper substrate into a true single crystal structure;
chemically removing the majority of the copper substrate to leave copper contacts that are interwebbed with the crystal structure of the metalloid; and
replacing the portion of the copper substrate that has been removed with material selected from the group comprising ceramics and hard plastics.

9. The online process according to claim 8, wherein the metalloid is germanium.

10. The online process according to claim 8, wherein a single crystal compound composed of zinc and selenium is grown on the metalloid.

11. The online process according to claim 8, wherein a single crystal compound composed of zinc and sulfur is grown on the metalloid.

12. The online process according to claim 8, wherein a single crystal compound composed of cadmium and tellurium is grown on the metalloid.

13. The online process according to claim 8, wherein a single crystal compound composed of cadmium, mercury and tellurium is grown on the metalloid.

14. The online process according to claim 8, wherein:
the copper substrate, the metalloid substrate, and a II-VI compound structure are all interwebbed;
the entire online process takes place in an inert gas atmosphere;
aside from the materials used to form the single crystals and the inert gas, and materials used in masking and etching, only materials selected from the group comprising stainless steel and graphite are used in the online process; and
the online process passes through control gates and chambers, in the following sequence:
a material cleaning and control gate;
a copper ribbon productions chamber, wherein the pressure is reduced to not more than ten millibars, and the chamber is then flooded with a mixture of nitrogen and hydrogen, then a copper ribbon is extruded directly from molten copper through an isotropic graphite jet, having optically flat inside surfaces;
a second control gate, through which the copper ribbon passes:
a germanium deposition chamber, filled with argon, where evaporated germanium falls as a deposited film onto the copper ribbon;
a third control gate, through which the copper ribbon with the germanium film passes;
an etching and support mounting chamber, in which the bottom of the copper ribbon is masked, and most of the copper ribbon is chemically removed and replaced with material selected from the group comprising ceramics and hard plastics, leaving copper contacts that interface directly with the germanium film;
a fourth control gate, through which the germanium film with the copper contacts passes;
a compound deposition chamber, filled with argon, where an evaporated II-VI compound falls as a deposited film onto the germanium film; and
an unloading and testing chamber, where the II-VI compound film and the germanium film with copper contacts come to air and exit for further handling.

15. An online process used to form a solar panel, comprising the steps of:
laying down a single crystal copper substrate, having a surface that is left unmachined and untreated;
growing a single crystal metalloid substrate onto the unmachined surface of the copper substrate, wherein the metalloid substrate is a framed and protected metalloid film of a defined thickness, having a surface that left unmachined and untreated, as the copper substrate includes copper contacts having single crystal structure at the bottom of the metalloid film; and
growing a single crystal II-VI compound structure onto the unmachined surface of the metalloid substrate, wherein compound structure is a single crystal coating of a II-VI compound over the metalloid film.

16. The online process according to claim 15, wherein the II-VI compound is composed of zinc and selenium.

17. The online process according to claim 15, wherein the II-VI compound is composed of zinc and selenium.

18. The online process according to claim 15, wherein the II-VI compound is composed of zinc and sulfur.

19. The online process according to claim 15, wherein the II-VI compound is composed of cadmium and tellurium.

20. The online process according to claim 15, wherein:
the copper substrate, the metalloid substrate, and the II-VI compound structure are all interwebbed;
the entire process takes place in an inert gas atmosphere;
aside from the materials used to form the single crystals and the inert gas, and materials used in masking and etching, only materials selected from the group comprising stainless steel and graphite are used in the online process; and
the online process passes through control gates and chambers, in the following sequence:
a material cleaning and control gate;
a copper ribbon productions chamber, wherein the pressure is reduced to not more than ten millibars, and the chamber is then flooded with a mixture of nitrogen and hydrogen, then a copper ribbon is extruded directly from molten copper through an isotropic graphite jet, having optically flat inside surfaces;
a second control gate, through which the copper ribbon passes:
a germanium deposition chamber, filled with argon, where evaporated germanium falls as a deposited film onto the copper ribbon;
a third control gate, through which the copper ribbon with the germanium film passes;
an etching and support mounting chamber, in which the bottom of the copper ribbon is masked, and most of the copper ribbon is chemically removed and replaced with material selected from the group comprising ceramics and hard plastics, leaving copper contacts that interface directly with the germanium film;
a fourth control gate, through which the germanium film with the copper contacts passes;
a compound deposition chamber, filled with argon, where an evaporated II-VI compound falls as a deposited film onto the germanium film; and
an unloading and testing chamber, where the II-VI compound film and the germanium film with copper contacts come to air and exit for further handling.
